(19) United States
(12) Patent Application Publication
(10) Pub. No.: US 2021/0310124 A1
(43) Pub. Date: Oct. 7, 2021

(54) COATING BY ALD FOR SUPPRESSING METALLIC WHISKERS

(71) Applicant: Picosun Oy, Espoo (FI)

(72) Inventor: Marko PUDAS, Masala (FI)

(73) Assignee: Picosun Oy, Espoo (FI)

(21) Appl. No.: 17/348,897

(22) Filed: Jun. 16, 2021

Related U.S. Application Data
(62) Division of application No. 16/093,055, filed on Oct. 11, 2018.

(51) Int. Cl. C23C 16/52; C23C 16/455; H05K 3/28; C23C 16/02; C23C 28/04

(52) U.S. Cl. CPC C23C 16/52; C23C 16/45529; C23C 16/45555; H05K 3/28; C23C 16/0227; H05K 1/0313; C23C 28/042; C23C 16/0209; C23C 16/45544; H05K 2201/0179; H05K 2201/0769; C23C 28/04

(57) ABSTRACT

A deposition method includes depositing on a surface of a substrate a stack by an ALD (atomic layer deposition). Also provided is an ALD reactor for carrying out the method and products obtained using the deposition method.

### FIELD

The aspects of the embodiments disclosed generally relate to atomic layer deposition techniques in which material is deposited onto a substrate surface.

### BACKGROUND

This section illustrates useful background information without admission of any technique described herein representative of the state of the art.

Atomic Layer Deposition (ALD) is a special chemical deposition method based on sequential introduction of at least two reactive precursor species to at least one substrate in a reaction space. Plasma enhanced ALD (PEALD) is an ALD method in which additional reactivity to the substrate surface is delivered in the form of plasma- produced species. Further, a related process is Atomic Layer Etching (ALE), which is ALD in reversed, and wherein conformal removal of one, possibly specific, atomic or molecular layer is removed with help of the specific chemistry. Further a subclass of ALD is MLD, Molecular Layer Deposition, which refers to depositing more than one atom per layer at time, and this often involves organic materials. Such materials are discusses in Beilstein J. Nanotechnol. 2014, 5, 1104-1136. Organic and inorganic-organic thin film structures by molecular layer deposition: A review, Pia Sundberg and Maarit Karppinen.

In the ALD processes, the substrates are not usually cleaned, as they are transferred to ALD tool in cleanroom from other clean process or from clean substrate box. Absorbed molecular layers from air or ambient, are usually mitigated by heating the commonly used silicon wafer substrates to temperatures up to 300 deg C. in inert gas flow. In contrast the normal reflow or manual soldering steps leave some traces of flux, which is harmful for ALD deposition. Further the for example PCB do not allow such high temperatures are silicon wafers do, and require different cleaning.

Metal whisker formation is an issue encountered especially with metals and metal alloys, such as Sn and Sn alloys, Cd and Cd alloys, and Zn and Zn alloys. Metal whiskers comprise metal spikes or other irregularities on the surface, which may cause short circuitry, corrosion, induced corrosion, increased accumulation of unwanted particles as a result of increased surface area and change RF performance of RF-lines and components. On the other hand, corrosion has been commonly referred to as a significant factor of whisker propensity. Metal whisker formation may start e.g. at electroplating of an electronics component or the board, at the soldering process of a printed circuit board (PCB), also known as reflow of solder paste, and cause problems even many years thereafter, regardless of the storage or use conditions of the PCB.

The issue of metal whiskers formation is critical in the case of electronic circuitry, but is also relevant with e.g. components used for e.g. electronics, and the casing of electronics, which is often made of electroplated metal.

In particular tin whisker formation has previously been significantly reduced by adding Pb in the alloy. However, due to toxicity of Pb, there is a need for new ways to mitigate or ultimately prevent tin whisker formation and possibly enhance corrosion protection. In particular filament type tin whisker formation in PCBs and electronic components may cause problems and, accordingly, there is a need for preventing their formation.

In literature various factors have been presented as affecting to the formation of tin whiskers. Such factors include: surface tension; temperature; humidity; electrical potential; electrostatic charge; and imperfect metal surfaces due to structural defects, oxide layers, grain boundaries, ionic contaminations, local stresses, and stress gradients. Some of these details are discussed in recent publication: Journal of Applied Physics 119, 085301 (2016), Surface parameters determining a metal propensity for whiskers, Diana Shvydka and V. G. Karpov.

### SUMMARY

According to a first aspect of the embodiements disclosed there is provided a deposition method to reduce metal whisker formation, electromigration and corrosion comprising:
providing a substrate
pretreating the substrate by cleaning
pretreating the substrate by preheating and/or evacuating; and
depositing a stack comprising depositing at least a first layer (100) by atomic layer deposition, ALD.

According to a second aspect of the present disclosure there is provided a use of the method of the first aspect for protecting substrates against metal whisker formation, electromigration and/or corrosion.

According to a third aspect of the present disclosure there is provided an ALD reactor system (700), comprising control means (702) configured to cause the ALD reactor system to perform the method of the first aspect.

According to an aspect is provided a device comprising a substrate deposited using the method of the first aspect.

Different non-binding example aspects and embodiments of the present disclosure have been illustrated in the foregoing. The above embodiments are used merely to explain selected aspects or steps that may be utilized in implementations of the present invention. Some embodiments may be presented only with reference to certain example aspects of the invention. It should be appreciated that corresponding embodiments may apply to other example aspects as well. Any appropriate combinations of the embodiments may be formed.

### BRIEF DESCRIPTION OF THE DRAWINGS

The disclosed embodiments will now be described, by way of example only, with reference to the accompanying drawings, in which:

FIG. 1 shows a flow chart of a method in accordance with an example embodiment.

FIG. 2 shows a schematic view of embodiments of a stack deposited on a substrate deposited using the present method.

FIG. 3 shows an ALD reactor system in accordance with an example embodiment.

FIG. 4A and FIG. 4B are SEM images showing reduced filament whisker formation on a SnAg sample (FIG. 4A) substrate coated using the method of the first aspect, compared with an uncoated control sample (FIG. 4B). The uncoated substrate in FIG. 4B with shows filament whiskers having a length of tens of μm's. FIG. 4A scale bar 10 μm, FIG. 4B scale bar 20 μm.

### DETAILED DESCRIPTION

In an embodiment the depositing step comprises a first pulse starting with at least one reductive chemical.

In an embodiment the depositing step comprises a first pulse starting with at least one oxidizing chemical.

In an embodiment the depositing step comprises a first pulse consisting of multiple pulses of the reductive chemical or chemicals followed by an inert gas pulse between them.

In an embodiment the metal comprises Zn, Zn alloy, Sn, Sn alloy, Cd or Cd alloy, Ag or Ag alloy.

In an embodiment the substrate comprises or is a printed circuit board, PCB. The substrate may be generally known as assembled PCB or PCB assembly with components, but it is referred to herein PCB. However, it should be noted that the process is applicable to semi-finished products, such as PCB-board or PCB with solder paste, or PCB with reflowed solder, electronics assembly or a partial assembly. In a further embodiment the substrate is a component, a component housing, a metal package, or a metal housing. Furthermore, a repair or reworking can and also be followed by the ALD coating described herein. In an embodiment the deposition process described hereinbefore and hereinafter forms a manufacturing phase of an electronic product.

Furthermore, a component which can be used as a part of the electronics of the PCB, or electronics assembly, may have a metallization coating or a metal package, which may form metal whiskers. Such coating methods include commonly known ‘immersion tin’ and alike. The presented method applies to such substrates as well.

The method is in an embodiment used to protect substrates, such as electronic components and electronic circuitry, including PCBs. The method and the use there is particularly useful in applications where quality and resistance to environment is of particular importance, such as in electronics intended for use in space, medical, industrial, automotive and in military applications.

In an embodiment the first layer (100) comprises layer of at least one ALD layer. The first layer is optionally adapted to adhere to the substrate 10. In an embodiment the adherence is the most optimal.

In an embodiment the stack further comprises depositing a second layer (200) by atomic layer deposition, ALD.

In an embodiment the second layer (200) comprises a number of sublayers. In an embodiment at least one sublayer is an elastic layer.

In an embodiment the second layer (200) consists of at least one elastic layer.

In an embodiment the second layer (200) consists of at least one organic layer or a silicone polymer containing layer.

As an example layer 200 is n*(I+II), where n>=1 and I is composed of at least two chemicals, such as TMA+H₂O, and II is any other combination of chemicals, of which at least one is different than in layer I. Further, any other combinations, such as n*(I+II+III) or n*(I+II)+m*(111+IV) or x{n*(I+II)+m*(111+IV)}, wherein m>=1, for example. Each of I, II, III and IV are composed of two chemicals of which at least one is different compared to each other, and optionally to the ones used in I and II.

In an embodiment the stack further comprises depositing a third layer (300) by atomic layer deposition, ALD.

In an embodiment the third layer (300) is a top layer.

In an embodiment pretreating the substrate by cleaning comprises cleaning by washing.

In an embodiment pretreating the substrate by cleaning comprises cleaning by solvents.

In an embodiment pretreating the substrate by cleaning comprises cleaning by blowing or cleaning by non-liquid fluids such as a gas or gasses.

In an embodiment pretreating the substrate by preheating comprises preheating with a pulse of heated gas with a temperature above the reaction temperature.

In an embodiment any of sublayers I, II and III independently comprises electrically insulating material.

In an embodiment layer II is an organic layer.

In an embodiment layer II is an organic or silicone polymer containing layer.

In an embodiment layer III is an organic or silicone polymer containing layer.

In an embodiment at least one of layers I, II, III and IV comprises reactive chemicals with ambient.

In an embodiment at least one of layers I, II and III is a hard layer.

In certain embodiments any of layers I, II and layer IV and layer IV is independently selected from an ALD layer, electrically insulating layer, oxide, carbide, metal carbide, metal, fluoride and nitride, including molecular layers deposited with molecular layer deposition, MLD.

In an embodiment layer II is a layer deposited with MLD thus effectively depositing multiple atoms at time, such as an organic layer, for example Alucone or Titanicone, or a layer containing various different atoms, for example C, N, Si and/or O. In a further embodiment, this layer forms polymer chains or crosslinking enabling the generally known mechanical strength or formation. Known examples of such crosslinking polymer structures are aliphatic polyureas, Hexa-2,4-diyne-1,6-diol with DEZ and TiCl₄, and silicone polymer —(SiR₂—O))n—. The effect of polymerization in an embodiment includes a combined effect via UV-polymerization, in ALD reactor, in vacuum cluster or outside the assembly.

In an embodiment layer II is an organic or silicone polymer chain-containing layer. Layer II is preferably resistant to cracking and enables deformation of the deposited layers. In an embodiment layer II is a cross-linked layer. In another embodiment layer II is a single layer or comprises multiple molecular layers. Thus, multiple layers of layer II may be deposited to provide a thicker laminate having elastic behavior as the whole stack. Such a layer is particularly advantageous to provide resistance to cracks caused e.g. by Hillock or a similar small formation in the first layer or stack, thus maintaining the corrosion resistance.

In an embodiment the thickness of the stack is 1-2000 nm, preferably 50-500 nm, most preferably 100-200 nm.

In an embodiment the method further comprises varying, stopping or limiting the fore-line exhaust flow. In an embodiment the varying, stopping or limiting is synchronized with a chemical pulse.

In an embodiment the method further comprises providing a further coating on top of the stack with a further coating method.

In an embodiment the further coating comprises polymer or silicone polymer, such as lacquer.

In an embodiment the further coating comprises providing a lacquer or like, or dip-coating for example, to the substrate.

In an embodiment the further coating comprises providing conventional organic or silicone polymer coating applied by conventional means, such as by spraying, brushing or by dip-coating.

In a further embodiment, in addition to or instead of the layer II, in the stack there is provided a layer comprising carbon nanotubes, a carbon nanotube net or a graphene network. In an embodiment, such a layer is covered, in an embodiment on all sides, with a layer of electrically insulating material, for example Al₂O₃. In a still further embodiment, the carbon nanotubes or the carbon nanotube net is configured to be electrically insulating.

In an embodiment the method comprises further depositing instead of or in addition to the second layer (200) a layer containing at least one sublayer comprising carbon nanotubes, a carbon nanotube net, or a graphene network.

In an embodiment the sublayer comprising carbon nanotubes, a carbon nanotube net, or a graphene network is coated with an electrically insulating material.

In an embodiment layer 300 is a top layer preventing hydrolysis, such as hydrolysis by wafer or moisture. In an embodiment layer 300 is a barrier layer. In a further embodiment layer 300 comprises Nb₂O₅. In a still further embodiment layer 300 comprises a further material resistant to hydrolysis, such as TiO₂, or an organic layer, for example and MLD layer comprising fluoropolymer. In an embodiment, the thickness of the top layer is in the range from one atomic layer to 20 nm, or 1-20 nm.

In an embodiment layer 300 is a top layer adapted to chemically adhere to the coating applied after the ALD process.

In an embodiment the stack comprises a hard layer instead of or in addition to layer I, II and/or III. In an embodiment, the hard layer comprises a layer of metal oxide. In a further embodiment, the hard layer is selected from Al₂O₃, TiO₂, Ta₂O₅, ZrO₂, SiO₂, Nb₂O₅, WO₃ an HfO₂, or a combination thereof in a single or repeated stack. Preferably the hard layer is a repeating stack, such as an Al₂O₃/TiO₂ repeating stack, i.e. a laminate.

In an embodiment at least one of layers I, II, III of the deposited layers in 100 or 200, comprises reactive chemicals intentionally left as excessive rations in the structure. Alternatively the oxide material may be reduced to reduce the ratio of oxygen. The reactive chemicals provide for an at least partially self-healing layer. The reactive chemicals are in an embodiment selected from chemicals reacting with ambient air or moisture. In an embodiment the reactive chemicals comprise for example TMA, or reduced Mg or Ti.

In an embodiment at least one of layers comprises at least one reactive chemical with ambient.

In an embodiment at least one of layers I, II and III is a hard layer.

In an embodiment the substrate comprises Sn. Depositing on Sn containing substrates is particularly advantageous because tin whisker formation can be at least partially prevented. Furthermore, in an embodiment, the substrate comprises Ag, which is commonly used in hybrid electronics and also benefits from tin whiskers protection in combination with preventing the easily occurring electromigration.

In an embodiment the method comprises carrying out the ALD coating as a high aspect ratio, HAR, pore coating in order to fill for example defects or cavities between layers of different material or under components on the PCB. This is preferable for polymer packages or for depositing interfaces between different materials of a PCB, such as interfaces between metal and other material used in construction of the PCB. In an embodiment high aspect ratio deposition is carried out at a lower temperature than the maximum deposition temperature. This is preferable for coating pores which close at higher temperatures due to the thermal expansion.

In an embodiment, the fore-line flow is varied with known processes or stop-flow or limited flow knows as PicoFlow is used in order to enable coating with significantly increased aspect ratio coating in cavities and increased uniformity of the coating.

In an embodiment, when depositing on substrates containing certain polymers, which may absorb the reactive chemicals or their metals or ligands, a low temperature process, as the whole process or at the start of the processes can be used, i.e. not more than 50 deg. C. is used to deposit a diffusion barrier for high temperature, and thus faster, deposition.

In an embodiment the total thickness of the deposited stack is sufficient to provide mechanical, chemical and electrical insulation properties to the substrate. In an embodiment the height of the stack is 1-2000 nm, preferably 50-500 nm, most preferably 100-200 nm. In an embodiment, the process contains pre-heating and cleaning of the substrate, followed by deposition of at least one atomic or molecular layer conformally with ALD.

In an embodiment the process temperature of the deposition is selected such that it corresponds to the maximum temperature the substrate can withstand. In an embodiment the process temperature is not said maximum temperature, but a temperature below such a maximum temperature. In the case of PCB for space applications, the process temperature may be 125 degrees C. In another embodiment, the process temperature is above boiling point of water at the selected pressure to prevent absorption and condensation on surfaces.

In an embodiment the substrate is a PCB and the method comprises soldering steps above the solder melting temperature, also known as reflow. This is advantageous in providing a structure without air bubbles in the solder or when manufacturing the PCB in a vacuum.

In an embodiment, the process temperature is below the soldering temperature, but with the help of the ALD process, the soldering effect occurs in a way that the solder particles or spheres are adhered together. This may further apply to adherence to substrate and to the components. It may be also that the ALD process is insufficient to cause final attachment via the solder, but the soldering step is carried out after the ALD process, in or out of the ALD tool.

In an embodiment, the substrate is partially masked before deposition to provide openings in the deposited stack.

In an embodiment, a stack of desired thickness can be deposited directly onto the substrate. The stack layers are deposited in the same ALD reactor or in a further ALD reactor(s).

The depositions of the stack may form manufacturing steps of the product, or be integrated to be a part of a production line.

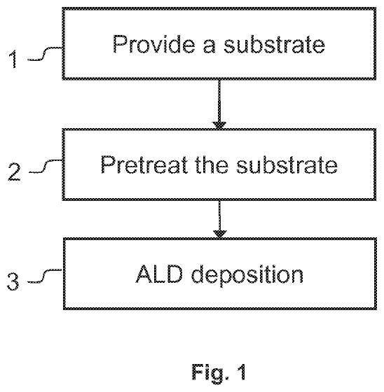

FIG. 1 shows a flow chart of a method in accordance with an embodiment of the invention. In step 1, a substrate intended for deposition is provided. The substrate comprises a substrate as described hereinbefore and hereinafter. In step 2, the substrate is pretreated, for example washed, cleaned or preheated either prior to inserting, or loading, the substrate into an ALD reactor or after the substrate has been inserted in the ALD reactor.

PEALD and ALD processes both can be used to clean the surface before the coating, using the plasma of the PEALD chemicals, or the gaseous chemical or multiple chemicals applicable in the ALD process.

In an embodiment, pretreatment of the sample includes various steps prior to inserting the sample to the ALD reactor to clean it, for example washing with solvents or by blowing. The fluids to be used in cleaning are in an embodiment chosen in accordance with the purpose of the cleaning, for example to remove ionic contamination and/or loose particles like dust.

In addition to the cleaning in the ALD rector, further surface cleaning methods comprise cleaning by hard Lewis Acids, or hard Lewis Bases. In an embodiment, cleaning includes cleaning with for example NH₃, HMDS, H₂, O₂, O₃ and/or TMA. In a further embodiment, the cleaning is done with the help of PEALD, wherein the plasma of the PEALD enables an even more effective cleaning.

In an embodiment the cleaning includes using heated Hz or 02 or 03.

Furthermore, in an embodiment, a reductive cleaning is done with H2, or chemicals having a similar effect in the gas phase, especially in the ALD processes, such as has been reported for 2-Methyl-1,4-bis(trimethylsilyl)-2,5-cyclohexadiene or 1,4-Bis(trimethylsilyl)-1,4-dihydropyrazine.

Thus, the cleaning is in an embodiment accomplished by a process which stabilizes the surface and provides a reductive gas pulse subsequent to the stabilization, said pulse comprising for example H₂, H₂ containing plasma, SO₃, or Al(CH₃)₃. This is referred to herein as a starting pulse, which is substantially the first pulse of reactive material released into the reaction chamber after stabilization. Further, in order to enhance the effect, it is preferable that the reductive chemical pulses follow each other with an interval, at least once by at least a delay of 0.01 s. More preferably the reductive chemical pulses are repeated at least 5 times, with a delay of 5 seconds therebetween, before the chemical reaction on the generated surface to increase material in ALD terms is added.

In an embodiment, the cleaning comprises ALE pulses. Atomic Layer Etching (ALE) is in an embodiment used as an alternative to cleaning or in addition to the cleaning to etch impurities from the surface, or preferably from a crystal boundary having a specific molecular composition. In ALE process the surface is removed possibly selectively and possibly from preferred chemicals only, in cycles of at least two steps as reversed ALD.

After the sample has been inserted into the ALD reactor, further pretreatment steps, for example ‘in-situ’ cleaning steps are performed in an embodiment. In an embodiment, pretreatment comprises surface cleaning by low temperature burning, such as by O₂, O₃or H₂ at a low temperatures, such as at 125 degrees C., or with gases at a temperature higher than that of the reactor space is. In an embodiment, the pretreatment includes a rinse with varying pressures and temperatures with an inert gas, or chemical gas. In an embodiment, the surface is exposed to a heated gas pulse, i.e. “burned”, oxidized or reduced, or chemical reactions are induced on the top surface.

The heated gas is used to provide heat treatment to surface materials, i.e. to the top layer of micro- or nanometer thickness range of the surface material, that otherwise would not withstand long exposure to elevated temperatures. Also, by using the heated gas pulse it is possible to provide heat treatment to the surface only, which is preferable when using heat sensitive substrates. Additionally, the outer layer of the solder is in an embodiment re-melted in this way without damaging or separating components. This results in annealing effects, which can affect the ally crystals in a manner similar to steel manufacturing steps. The temperature increase of the whole substrate in an embodiment is below the temperature of the actual melting temperature of the metal.

In an embodiment the heat pulse is carried out by providing a heat pulse for a certain time, such as 0.01-100 s, depending on the used gas, reaction chamber temperature, used gas flow rates and other gas flow rates In a still further embodiment, the temperature of the heat pulse gas is raised with a heated gas inlet configured to heat the gas to a high temperature, for example up to 1000 degrees C. The pulse mass flow is in an embodiment smaller, e.g. 0.1-50 sccm, same, e.g. 20-500 sccm, or significantly larger, e.g. 200-20000 sccm, than the other incoming gas flow or flows to the reactor at the time. In combination or separately such different temperature gas flows are in an embodiment used for cooling the coated materials equally, thus enabling separately or in combination the surface metallurgical modification of the materials coated. This is commonly known in the processing of steel, but for bulk, and thus is dependent on metals used. This results in similar annealing effects, which can affect the ally crystals in such manner as in steel manufacturing steps.

Furthermore, in an embodiment, the reactor is realized with one or more optical or contact sensor(s) arranged to determine the temperature of the coated substrates.

In a still further embodiment, the pretreatment is carried out in the ALD reactor by evacuating. In a further embodiment the evacuating step is accompanied by heating in an atmosphere of an inert gas, such as nitrogen, in order to cause annealing of the surface.

In an embodiment, in the deposition step, a stack, as described hereinbefore and hereinafter, is deposited on the substrate by ALD.

Further, depending on the application, the applied ALD layer is, in an embodiment, further coated with a further coating method, for example coated with a lacquer, e.g. for improved mechanical durability. Furthermore, the ALD layer enables further coating with dip-coating processes, which might otherwise harm the PCB structure, e.g. due to the solvents used, and thus the ALD layer enables application of such new processes. The benefit of ALD alone over other coatings, should no further coating be applied, is that there is no significant increase in mass or dimensions of the coated object, as ALD layers are usually ˜100 nm thick, conformally.

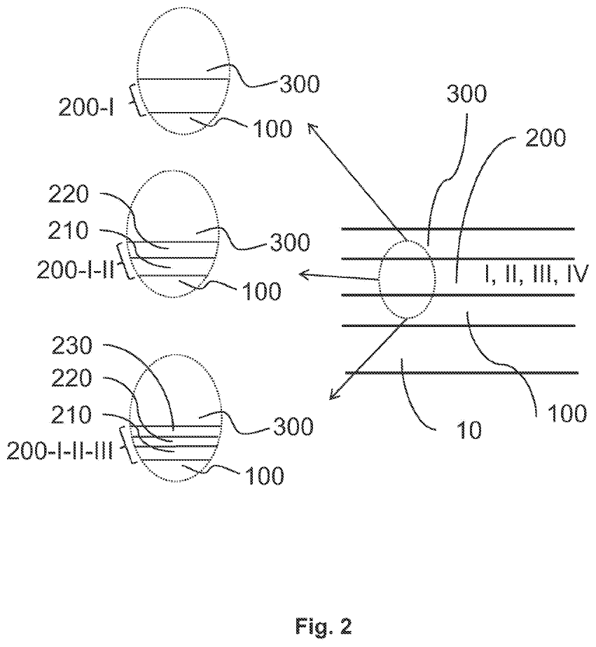

FIG. 2 shows a schematic view of embodiments of a stack deposited on a substrate deposited using the present method. A substrate 10 is deposited by stacked layers 100, 200 and 300. Layer 100 is in the interface to the substrate, and is referring here to one deposited material, such as Al₂O₃. Layer 200 consists of a single layer or sublayers, such as I, II, II, III, and IV, or a combination thereof, of which at least one is elastic or contains crosslinked chains of carbon, organic material or silicone polymer. In an embodiment layer 200 consist of any number of combinations or repetitions of at least one sublayer I, II, III and IV.

300 is surface layer, which has the function of protecting against surface chemical reactions, such as hydrolysis. Alternatively or additionally it may contain chemicals adapted to chemically adhere with possible layers of organics, like lacquer, added after the ALD process.

FIG. 2 shows a schematic view of embodiments of a stack deposited on a substrate deposited using the present method. A substrate 10 is deposited by stacked layers 100, 200 and 300. Different embodiments of the first layer are illustrated on the left hand side. Layer 200-I is an embodiment of layer 200 and illustrates an embodiment wherein only a single layer of layer I is deposited on the surface. Layer 200-I-II is an embodiment of layer 200 and illustrates an embodiment wherein the layer 200 is formed by layers I and II, corresponding to sublayers 210 and 220, respectively, and as defied above. Layer 200-I-II-III is an embodiment of layer 200 and illustrates an embodiment wherein the layer 200 is formed by layers I, II, and III, corresponding to sublayers 210, 220, and 230 respectively, and as defined above. In an embodiment in structures 200-I-II and 200-I-II-III the layered structure is repeated at least 2 times (not shown in FIG. 2).

When the substrate is a PCB, and the method is used during manufacturing process of the PCB or a device using it, a layered stack is formed on the substrate. The stack may provide protection and prevent tin whisker formation in the PCB, thus increasing quality and resistance to corrosion and damage during use.

The layers 100-300 are deposited in a conventional manner in an ALD reactor. The layers 100, 200 and 300 are deposited by ALD on top of the substrate.

An example of a minimum stack, excluding the cleaning, is x(TMA+H₂O), where x is the number of cycles needed to produce the required layer thickness at the used temperature, such as x=1000 at 125 deg C. This represents layer I.

Another example of a stack is
z{x(TMA+H₂O)+y(TMA+EthylGlygol)}, where ratios of a, y and z can be adjusted to modify the required mechanics properties, where x, y and z are same or different and/or larger than 1. This represents layers I and II. Optionally layer II is anything else than only I.

Another example of a stack is
z{x(TMA+H₂O)+y(TMA+EthylGlygol)}+n(Nb(OEt)₅+H₂O), where the Nb-containing layer creates the layer which is very difficult to be hydrolysed. This represents layers II(a), II(b) and III, where first occurrence of II(a) is effectively the layer I.

For clarification, layer 200 may consists of any number of sublayers II, such as y(TMA+EthylGlygol) or stacked x(TMA+H₂O)+y(TMA+EthylGlygol).

Another example of a stack is a stack wherein the created Al₂O₃ layer from TMA+H₂O is replaced with oxides such as TiO₂ to combination of variation of Al₂O₃+TiO₂ for example. Following structures can be created where TiCl₄ is considered as the precursor of the TiO₂:

(TMA+H₂O)→(TMA+H₂O)+(TiCl₄+H₂O)

or any combination in way of

z{x(TMA+H₂O)+n(TiCl₄+H₂O)+y(TMA+EthylGlygol)+}+m(TMA+H₂O)

where m and n are same or different and/or larger than 1.

Another example is TMA+EthylGlygol, known generally as AB replaced to TMA+EthylGlygol+H₂O (ABC), where the added water is intended to react with unreacted TMA. Layer II can contain either AB or ABC.

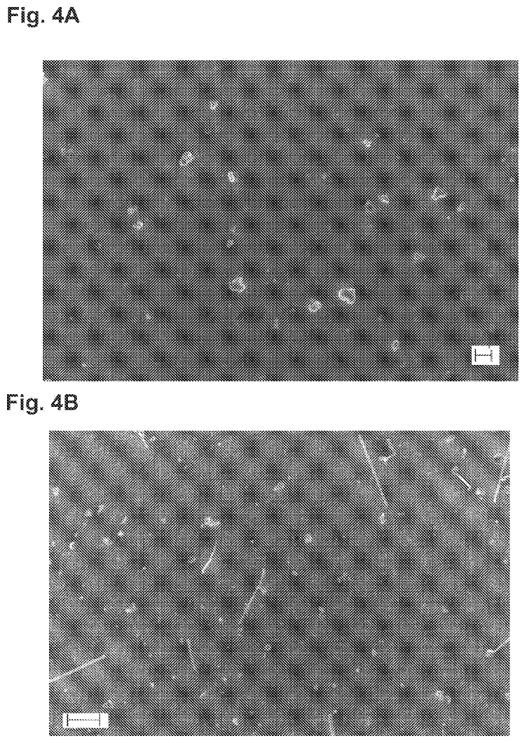

As shown in the FIGS. 4A and 4B, the ALD coating made of laminated Al₂O₃ and Alucone according to an embodiment of the first aspect of the invention, is able to prevent filament type tin whisker growth after 6 month in ambient storage. The samples were prepared with electroplating ˜2 μm SnCu on copper and intended to create spontaneously tin whiskers with accelerated speed. The ALD coating was ˜500 nm thick: Al₂O₃+19*(Al₂O₃+Alucone)+Al₂O₃. The ALD coating was done four days after the initial metal coating, at which time the formations shown at left side, were already visible. This structure refers to stack of 100, 200 and 300, where 100 and 300 are here the same material.

In a further embodiment the ALD, including MLD and ALE, growth on PCB is blocked at some positions by using specific chemistry and process in order to deposit only on the alloy surface intended, for example on the solder but not on the dielectric material. Such targeted deposition can be enabled by blocking the growth on non-desired places, for example dielectrics, with the help of chemicals as commonly known as ALD growth inhibitors, which include materials, such as self-assembly monolayer of certain silanes. The chemistry of this inhibition coating, inside or outside the reactor, can be tailored so that it does not coat the solder, for example. Such specific coating enables for example solder surface coating with thin films of possibly conductive layers, which can be preferred in some cases to change the surface tension of the solder. Thus, it is evident that if the surface tension can be changed without compromising the electrical surface insulation, the patterning presented herein is not needed to be applied with a mask or marking.

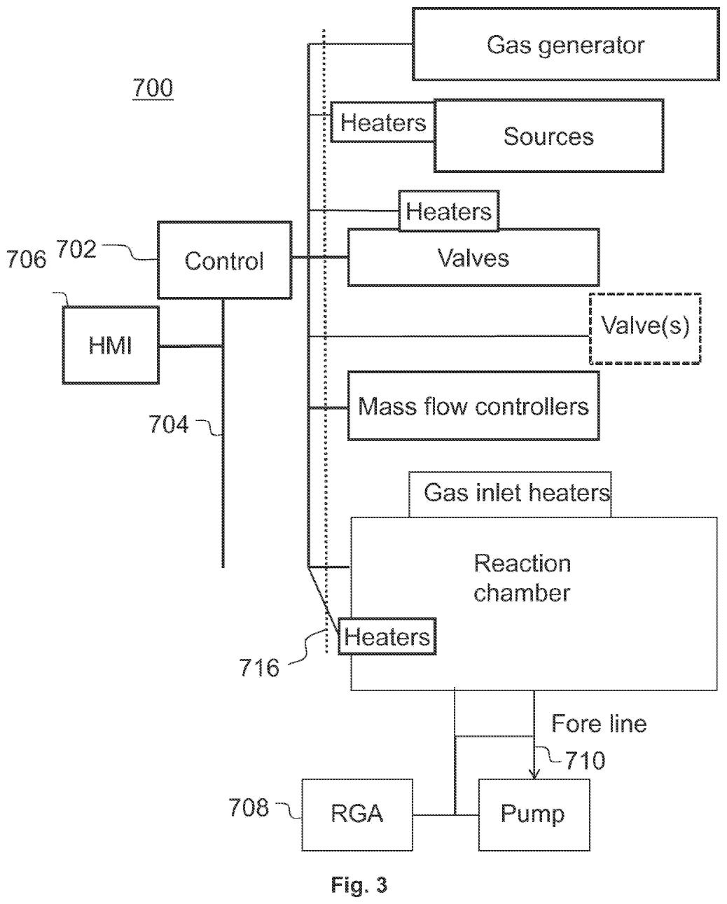

FIG. 3 shows an ALD reactor system 700, i.e. the reactor and a control system thereof in accordance with an example embodiment. In an embodiment, the ALD reactor comprises a reaction chamber wherein a substrate, e.g. PCB, semi-finished assemblies or components board assemblies can be loaded in an appropriate manner, for example, the reactor can be integrated to a production line so that a production line can travel through the ALD reactor. A precursor source or sources is in an embodiment provided in fluid communication via an in-feed part with the reaction chamber of the reactor. Reaction residue from the reaction chamber may be pumped via a vacuum pump into exhaust, i.e. fore-line. The ALD reactor may be in fluid connection to means for monitoring cleaning between the method steps described herein.

In an embodiment, the system comprises measurement means 708 configured indicate sufficient degassing, and/or drying and/or dosing of reactive chemicals to the substrate. In an embodiment, such means include for example a mass spectrometer and/or optical means configured to measure a chemical content or signature or pressure of gases outgoing from the reactor, from inside the reactor, from fore-line or after the pump. This system is generally known as Residual Gas Analyzer, RGA. In an embodiment, the RGA 708 is configured to communicate with control means 702 or a HMI 706 or a separate user interface in order to indicate the chemical or elementary content or a fingerprints of a gasses from reactor or of fore-line 710 gases and their concentration. For high quality ALD reaction it is for example important that all of the reactive gas is flushed out down to a quantity of for example below 1 part in 1000 or more preferably below 1 PPM. In an embodiment, the RGA 708 is used to sample all out-coming gases form the reaction chamber. In a further embodiment, the RGA is used to quantify the amount and quality of out-coming gases in ambient, heated or chemically exposed conditions of the substrate(s) that is required for example in space applications.

In an embodiment, the fore-line 710 comprises heating means in order to substantially prevent, or at least significantly reduce, undesired particle generation. The heating means are in an embodiment positioned upstream of vacuum reducing valves in the fore-line 710.

In an embodiment the ALD reactor system (700) comprises at least one further gas inlet configured to be heated separately from other gas inlets to at least temperature of 500 deg C.

In an embodiment the at least one further gas inlet is made of ceramic material, or metal or metal coated with ceramic material.

In an embodiment the at least one further gas inlet is configured to be heated in an intermediate space of the reactor.

In an embodiment the ALD reactor system (700) comprises gas inlets configured to enable pulsing H₂, O₂ and/or O₃.

In an embodiment the ALD reactor system (700) comprises gas inlets configured to withstand heat which is higher than the reaction chamber temperature.

In an embodiment the ALD reactor system (700) comprises gas inlets configured to enable gas pulse with a temperature difference of at least 100 dec C, compared to the reactor space.

The intermediate space refers to an inner part of the ALD reactor, which is evaluated to pressure below ambient pressures and/or filled with inert gas, and further arranged not to be in contact with reactive chemicals.

The deposition process and the reactor system is in an embodiment controlled by a control system. In an example embodiment, the ALD reactor is a computer-controlled system. A computer program stored into a memory of the system comprises instructions, which upon execution by at least one processor of the system cause the ALD reactor to operate as instructed. The instructions may be in the form of computer-readable program code. In a basic system setup according to an embodiment, process parameters are programmed with the aid of software and instructions are executed with a human machine interface (HMI) terminal 706 and downloaded via Ethernet bus 704 to a control means 702. In an embodiment, the control means 702 comprises a general purpose programmable logic control (PLC) unit. The control means 702 comprise at least one microprocessor for executing control software comprising program code stored in a memory, dynamic and static memories, I/O modules, A/D and D/A converters and power relays. The control means 702 send electrical power to pneumatic controllers of in-feed line valves of the ALD reactor, and is in two-way communication with in-feed line mass flow controllers, and precursor source or sources as well as otherwise controls the operation of the ALD reactor. The control means 702, in an embodiment, measure and relay probe, sensor or measurement means readings from the ALD reactor or gas lines thereof to the HMI terminal 706. A dotted line 716 indicates an interface line between the ALD reactor parts and the control means 702. The HMI terminal 706 and control means 702 can be combined as one module.

The inventors have established that the method as hereinbefore described with a combination of pretreatment and deposition of at least one layer with ALD substantially prevents, or at least significantly reduces, the formation of metal whiskers, especially of metal whiskers of the filament type.

Without limiting the scope and interpretation of the patent claims, certain technical effects of one or more of the example embodiments disclosed herein are listed in the following: A technical effect is preventing formation of tin whiskers. Another technical effect is providing resistance to corrosive chemicals such as water or sulphur. Another technical effect is prevention of electromigration optionally caused by moisture. Another technical effect is increasing mechanical strength of ALD layer such as a hard ALD layer. Another technical effect is protection of conductive material where tin whisker formation is possible. Another technical effect is protection from gas corrosion. Another technical effect is provision of a low cost manufacturing process. Another technical effect is that the deposited stack can be opened, e.g., by laser, for reworking such as connecting or contacting.

The method and tool provided here enable at the same time with the tin whiskers mitigation the creation of corrosion barrier against corrosive gasses, moisture, liquids (depending on the used coating), such as water. Also the process enables the protection against electromigration, which is also known in the form of dendrite formation.

Furthermore, the provided method prevents corrosion on the PCB surface, which is mostly related liquid, condensate or moist air on the metal surfaces.

Furthermore, the main benefit of using ALD in the PCB for mitigating the tin whisker issues is that the ALD layer can be reworked in the repair process, by removing the coating for example mechanically or with a laser. Moreover, it is possible to attach components on top of the soldered parts with ALD coating, as the ALD layer in between the solder under the ADL and possible added component, e.g. solder paste, will effectively break away the hard insulating material.

Further benefit of the present disclosure is that it enables the protection of the target components or board, possibly with components, referred to as PCB herein, from tin-whiskers, corrosion, electrical breakthrough, e.g. via ambient environment, for example where the e.g. component legs are left uncoated, or against electromigration.

Still further, BGA, Ball Grid Array, component undercoating is made possible with ALD, which is not possible with other protection methods due very high aspect rations.

The foregoing description has provided by way of non-limiting examples of particular implementations and embodiments of the present disclosure a full and informative description of the best mode presently contemplated by the inventors for carrying out the present disclosure. It is however clear to a person skilled in the art that the present disclosure is not restricted to details of the embodiments presented above, but that it can be implemented in other embodiments using equivalent means without deviating from the characteristics of the present disclosure.

Furthermore, some of the features of the above-disclosed embodiments may be used to advantage without the corresponding use of other features. As such, the foregoing description should be considered as merely illustrative of the principles of the present embodiments, and not in limitation thereof. Hence, the scope of the embodiments is only restricted by the appended patent claims.

1. An atomic layer deposition reactor system, comprising:
control means;
a reaction chamber;
means configured to preheat a substrate inside the reaction chamber; and
means for depositing by ALD, inside the reaction chamber, a coating comprising at least a first layer on the substrate; wherein
the control means is configured to control the operation of the ALD reactor system,
and the ALD reactor system further comprises at least one ceramic gas inlet in fluid communication with the reaction chamber.

2. The ALD reactor system of claim 1, wherein the ceramic gas inlet is configured to withstand heat which is higher than the temperature used in operating the ALD reactor system.

3. The ALD reactor system of claim 1, wherein the ceramic gas inlet is configured to enable gas pulsing with a temperature difference of at least 100° C. compared to the reactor space.

4. The ALD reactor system of claim 1, wherein the ceramic gas inlet is configured to be heated in an intermediate space of the ALD reactor system.

5. The ALD reactor system of claim 1, wherein the ceramic gas inlet is arranged on the wall of the reaction chamber.

6. The ALD reactor system of claim 1 comprising one or more optical or contact sensor(s) configured to determine the temperature of the coated substrate.

7. The ALD reactor system of claim 1 comprising a fore-line in fluid connection with the reaction chamber.

8. The ALD reactors system of claim 7, wherein the fore-line further comprises means for varying, stopping, and/or limiting gas flow through the fore-line.

9. An ALD method carried out in the ALD reactor system of claim 1, wherein the ceramic gas inlet is used to feed into the reaction chamber gas having a temperature which is higher than the ALD deposition temperature.

10. The ALD method of claim 9, wherein the ALD reactor system further comprises a fore-line in fluid communication with the reaction chamber, and wherein the ALD method further comprises varying, stopping and/or limiting a flow through the fore-line.
